(19) United States
(12) Patent Application Publication
(10) Pub. No.: US 2010/0103655 A1
(43) Pub. Date: Apr. 29, 2010

(54) ELECTRONIC SKYLIGHT SYSTEM

(76) Inventor: Andrew N. Smith, Healdsburgh, CA (US)

Correspondence Address: LITMAN LAW OFFICES, LTD., POST OFFICE BOX 41200, SOUTH STATION, ARLINGTON, VA, 22204, US

(21) Appl. No.: 12/588,653

(22) Filed: Oct. 22, 2009

Related U.S. Application Data
(60) Provisional application No. 61/193,113, filed on Oct. 29, 2008.

(51) Int. Cl. F21L 4/00; F21S 4/00; H01L 31/042

(52) U.S. Cl. 362/183; 362/249.02; 362/249.01; 136/244

(57) ABSTRACT

The electronic skylight system includes an exterior mounted photovoltaic solar panel electrically connected to power-switched, ceiling-mounted LED light sources to simulate a traditional skylight. The photovoltaic (PV) panel output is routed to a distribution box that provides power to the LED array(s). Disposed between the PV panel and the distribution box is an optional 12-volt battery with charge controller and battery protection. The PV or battery power source activates the ceiling-mounted LED light array(s). Power switching in the LED arrays allows a user to turn off the arrays when the room needs to be darkened. Power from one photovoltaic panel can illuminate multiple rooms. The light output per room can be adjusted by using various power levels of LED lights.

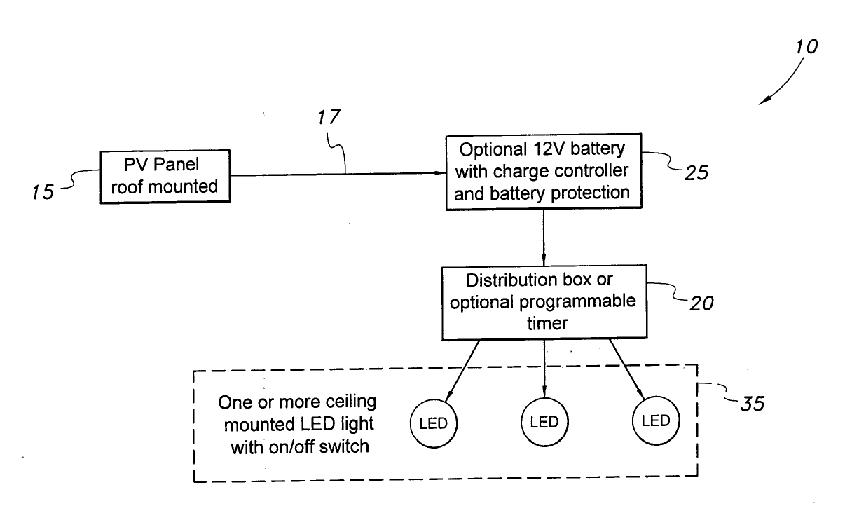

### CROSS-REFERENCE TO RELATED APPLICATION

This application claims the benefit of U.S. Provisional Patent Application Ser. No. 61/193,113, filed Oct. 29, 2008.

### BACKGROUND OF THE INVENTION

1. Field of the Invention

The present invention relates generally to lighting systems, and particularly to an electronic skylight system that simulates a traditional, natural light skylight.

2. Description of the Related Art

Skylights are generally not easy to install in retrofit applications because there is usually a need to cut a large hole in a roof and risk water leaks in doing so. Moreover, radiant heat gain or insulation loss results from a large hole in a roof and ceiling to accommodate a natural lighting skylight.

Additionally, without the added complexity and expense of automatic shutters, the natural lighting skylight offers no ability to turn off the light when it is desired to have a darkened room. It is not very easy to illuminate multiple rooms from the one large hole in the roof. And, of course, when the sun goes down, the utility of the skylight as a light source is diminished.

Thus, an electronic skylight system solving the aforementioned problems is desired.

### SUMMARY OF THE INVENTION

The electronic skylight system includes a roof-mounted photovoltaic solar panel electrically connected to power-switched, ceiling-mounted light emitting diode (LED) light sources to simulate a traditional skylight. The photovoltaic (PV) panel output is routed to a distribution box that provides power to the LED array(s). Disposed between the PV panel and the distribution box is an optional 12-volt battery with charge controller and battery protection. The PV or battery power source activates the ceiling-mounted LED light array(s). Power switching in the LED arrays allows a user to turn off the arrays when the room needs to be darkened. Power from one photovoltaic panel can illuminate multiple rooms. The light output per room can be adjusted by using various power levels of LED lights.

These and other features of the present invention will become readily apparent upon further review of the following specification and drawings.

### BRIEF DESCRIPTION OF THE DRAWINGS

The sole FIGURE is a block diagram of an electronic skylight system according to the present invention.

Similar reference characters denote corresponding features consistently throughout the attached drawings.

### DETAILED DESCRIPTION OF THE PREFERRED EMBODIMENTS

As shown in the drawing, the electronic skylight system 10 includes a preferably roof-mounted photovoltaic solar panel 15 electrically connected to one or more ceiling-mounted, high efficiency light sources 35, preferably LEDs, to simulate the light-producing effect of a skylight. In lieu of LEDs, an array of compact fluorescent light sources may provide the illumination.

The output of roof-mounted photovoltaic (PV) panel 15 is routed via a single roof-penetrating 2-conductor cable 17 to a distribution box 20, thereby providing power to a single switched LED array, or a plurality of power switched LED arrays 35, that may be mounted in disparate locations throughout an interior space. Disposed between the PV panel 15 and the distribution box 20 is an optional twelve-volt battery with charge controller and battery protection 25. The PV power source 15 or battery power source 25 activates one or more of the power-switched ceiling-mounted LED light arrays 35. The power-switched LED light arrays 35 allow the user to switch LED light arrays on or off for customized lighting control.

Multiple rooms, i.e., disparate interior spaces, can be illuminated from power provided by one photovoltaic panel 15. The light output per room can be adjusted by using various power levels of LED lights in the arrays 35. The battery backup with charge controller and battery protection 25 may be provided to extend the lighting into the evening hours and on overcast days. A timer shutting on/off the LED arrays 35 may also be included in the distribution box 20.

It is to be understood that the present invention is not limited to the embodiment described above, but encompasses any and all embodiments within the scope of the following claims.

I claim:

1. An electronic skylight system, comprising:
a photovoltaic panel adapted for mounting on an exterior of a structure;
a cable having two conductors electrically connected to the photovoltaic panel, the cable being adapted for penetrating into an interior space of the structure;
a distribution box electrically connected to the cable, the distribution box having an output adapted for routing power to a plurality of interior locations; and
at least one power-switched LED array accepting the output from the distribution box, the array being adapted for mounting on a ceiling of the interior space.

2. An electronic skylight system, comprising:
a photovoltaic panel adapted for mounting on an exterior of a structure;
a cable having two conductors electrically connected to the photovoltaic panel, the cable being adapted for penetrating into an interior space of the structure;
a distribution box electrically connected to the cable, the distribution box having an output adapted for routing power to a plurality of interior locations; and
at least one power-switched electrical light source accepting the output from the distribution box, the electrical light source being adapted for mounting on a ceiling of the interior space.

3. The electronic skylight system according to claim 2, wherein the electrical light source is an array of compact fluorescent lamps.

4. The electronic skylight system according to claim 2, wherein the electrical light source is an array of light emitting diodes.

5. The electronic skylight system according to claim 2, wherein arrays of said electrical light source are mounted in disparate locations throughout the interior space.

6. The electronic skylight system according to claim 5, wherein said arrays have electrical lights having adjustable power levels for adjusting light output in each of the disparate interior spaces.

7. The electronic skylight system according to claim 2, further comprising:
a battery with charge controller and battery protection disposed between the PV panel and the distribution box; and
a switch electrically connecting the battery to the distribution box.

8. The electronic skylight system according to claim 2, further comprising a timer controlling power to the electrical light source, the timer being disposed in said distribution box.
